(19) United States
(12) Patent Application Publication
(10) Pub. No.: US 2026/0229181 A1
(43) Pub. Date: Aug. 6, 2026

(54) DISPLAY DEVICE

(71) Applicant: LG Display Co., Ltd., Seoul (KR)

(72) Inventors: Jinhun KIM, Goyang-si (KR); Juhee EUN, Seoul (KR); Juhwan BAEK, Seoul (KR); Yeonjin SA, Seoul (KR)

(73) Assignee: LG Display Co., Ltd., Seoul (KR)

(21) Appl. No.: 19/451,707

(22) Filed: Jan. 16, 2026

(30) Foreign Application Priority Data
Jan. 20, 2025 (KR) 10-2025-0008278

(51) Int. Cl. G09G 3/3233

(52) U.S. Cl. CPC G09G 3/3233; G09G 2300/0842; G09G 2310/08; G09G 2320/0247; G09G 2330/027; G09G 2340/0435

(57) ABSTRACT

The display device is configured to: upon receiving a power-off command, to change an operation frequency of a pixel, and to perform a refresh frame operation of refreshing the pixel, based on the changed operation frequency; and after the refresh frame operation, execute a power-off sequence. In this way, a FOS (front of screen) problem that may occur at a power-off time may be suppressed.

### CROSS-REFERENCE TO RELATED APPLICATION

The present application claims priority to Korean Patent Application No. 10-2025-0008278, filed on January 20, 2025, the entire contents of which is incorporated herein for all purposes by this reference.

### BACKGROUND

### Technical Field

The present disclosure relates to a display device.

### Description of Related Art

An organic light-emitting display device is a self-emission display device. Unlike a liquid crystal display device, a separate light source is not required in the organic light-emitting display device. Thus, the organic light-emitting display device may be manufactured in a lightweight and thin type. In addition, the organic light-emitting display device is advantageous in terms of power consumption due to low voltage operation, and has excellent color gamut, high response speed, wide viewing angle, and high contrast ratio (CR), and thus is being studied as a next-generation display device.

The display device has been continuously improved to increase the resolution and luminance of a screen to provide a clear image to the user.

### BRIEF SUMMARY

An oxide thin-film transistor (oxide TFT) is applied to a pixel structure of a display panel to reduce power consumption and have excellent hysteresis characteristics, and a narrow bezel. In such a pixel structure, low-frequency operation may be effectively implemented due to excellent hysteresis characteristics of the oxide TFT.

However, in the display device having such a pixel structure, residual charges may be generated in a node due to the excellent off-current characteristic of the oxide TFT. When the display device operates at a low frequency for a long time, a front of screen (FOS) problem such as

flashing may occur at a power-off time due to rising of a gate low voltage VGL or the residual charges. Accordingly, the inventors of the present disclosure have invented a display device capable of suppressing the FOS problem that may occur at the power-off time by refreshing a node of a pixel via the high frequency operation before entering a power-off sequence.

A technical purpose to be achieved according to an embodiment of the present disclosure is to provide a display device capable of suppressing the FOS (front of screen) problem that may occur at a power-off time by refreshing a node of a pixel via the high-frequency operation at a power-off and then entering a power-off sequence.

In addition, a technical purpose to be achieved according to an embodiment of the present disclosure is to provide a display device capable of preventing an abnormal operation such as flashing by discharging residual charges in each node of a pixel in a power-off sequence.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure is provided. The display device is configured to: upon receiving a power-off command, to change an operation frequency of a pixel, and to perform a refresh frame operation of refreshing the pixel, based on the changed operation frequency; and after the refresh frame operation, execute a power-off sequence.

According to an embodiment, in the power-off sequence, the display device is configured to apply a data voltage corresponding to a black pattern to the pixel, apply a ground voltage to the pixel to discharge residual charges of each node of the pixel, and maintain a potential of each node of the pixel at the ground voltage for a predetermined time duration or greater to minimize turn-off-coupling of the transistor.

According to an embodiment of the present disclosure, the display device may suppress the FOS problem that may occur at a power-off time by refreshing the node of the pixel via changing the operation frequency at the power-off and performing the refresh operation based on the changed operation frequency and then entering and executing the power-off sequence.

In addition, the display device may prevent the abnormal operation such as flashing by discharging residual charges in each node of the pixel in the power-off sequence.

In addition, upon receiving the power-off command in a low-frequency operation condition in the pixel including a plurality of oxide TFTs, the display device can solve a problem in which flashing occurs by refreshing the node of the pixel via the high-frequency operation and then entering and executing the power-off sequence.

In addition, the display device refreshes the node of the pixel via the high-frequency operation upon receiving the power-off command, thereby preventing the gate low voltage from rising, and thereby reducing stress of the nodes of the pixel.

In addition, the display device may discharge the residual charge in the pixel by executing the power-off sequence as described above, thereby maintaining the performance of the element, and suppressing the FOS problem that may otherwise occur, and rather, improving the FOS-related performance of the display.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a block diagram schematically illustrating an organic light-emitting display device according to an embodiment of the present disclosure.

FIG. 2 is a circuit diagram of a pixel in an organic light-emitting display device according to an embodiment of the present disclosure.

FIG. 3 is a circuit diagram of a pixel showing an initialization operation in an organic light-emitting display device according to an embodiment of the present disclosure.

FIG. 4 is a circuit diagram of a pixel showing a sampling operation in an organic light-emitting display device according to an embodiment of the present disclosure.

FIG. 5 is a circuit diagram of a pixel showing a program operation in an organic light-emitting display device according to an embodiment of the present disclosure.

FIG. 6 is a circuit diagram of a pixel showing a light-emitting operation in an organic light-emitting display device according to an embodiment of the present disclosure.

FIG. 7 is a circuit diagram of a pixel showing an anode reset operation in an organic light-emitting display device according to an embodiment of the present disclosure.

FIG. 8 is a timing diagram illustrating a refresh frame operation in an organic light-emitting display device according to an embodiment of the present disclosure.

FIG. 9 is a timing diagram illustrating an anode reset frame operation in an organic light-emitting display device according to an embodiment of the present disclosure.

FIG. 10 is a timing diagram illustrating a low frequency operation in an organic light-emitting display device according to an embodiment of the present disclosure.

FIG. 11 is a circuit diagram illustrating a pixel state in the low frequency operation of FIG. 10.

FIG. 12 is a flowchart illustrating a power-off operation in an organic light-emitting display device according to an embodiment of the present disclosure.

FIG. 13 is a timing diagram illustrating a power-off operation in an organic light-emitting display device according to an embodiment of the present disclosure.

FIG. 14 is a flowchart illustrating a power-off sequence in an organic light-emitting display device according to an embodiment of the present disclosure.

FIGS. 15 to 18 are circuit diagrams of a pixel showing a power-off sequence in an organic light-emitting display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc., disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In descriptions of temporal relationships, for example, temporal precedent relationships between two events such as “after”, “subsequent to”, “before”, etc., another event may occur therebetween unless “directly after”, “directly subsequent” or “directly before” is indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. In interpreting a numerical value, the value is interpreted as including an error range unless there is no separate explicit description thereof. Further, the term ‘or’ means ‘inclusive or’ rather than ‘exclusive or’. That is, unless otherwise stated or clear from the context, the expression that ‘x uses a or b’ means one of natural inclusive permutations.

Hereinafter, according to an embodiment of the present disclosure, a display device capable of suppressing the FOS (front of screen) problem that may occur at a power-off time by refreshing a node of a pixel via high-frequency operation at power-off and then entering and executing a power-off sequence is disclosed. In addition, according to an embodiment of the present disclosure, disclosed is a display device capable of preventing an abnormal operation such as flashing by discharging residual charges in each node of a pixel in a power-off sequence.

Hereinafter, various embodiments of the present disclosure will be described in detail with reference to the accompanying drawings.

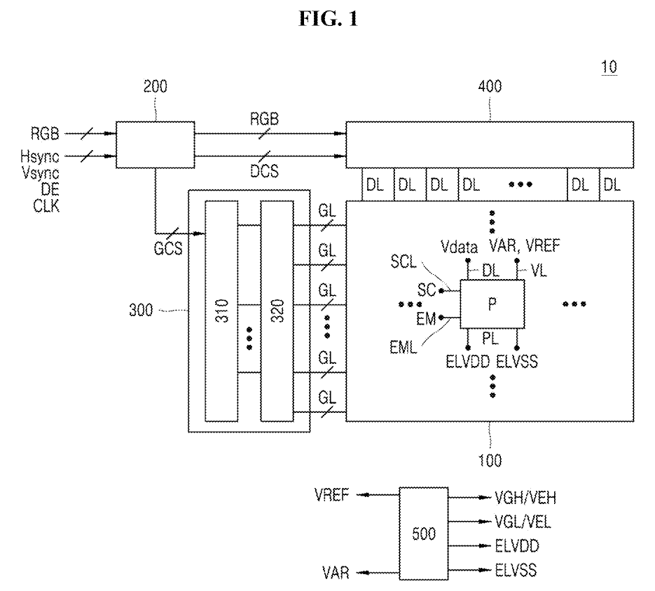

FIG. 1 is a block diagram schematically illustrating an organic light-emitting display device according to an embodiment of the present disclosure.

Referring to FIG. 1, a display device 10 includes a display panel 100 including a plurality of pixels P, a controller 200, a gate driver 300 configured to supply a scan signal SC to the plurality of pixels P, a data driver 400 configured to supply a data voltage Vdata to the plurality of pixels P, and a power supply 500 configured to supply voltages required for driving the plurality of pixels P.

In the display panel 100, a plurality of gate lines GL and a plurality of data lines DL intersect each other, and each of the plurality of pixels P is connected to the gate line GL and the data line DL. Specifically, one pixel P receives the scan signal SC from the gate driver 300 via the gate line GL, receives the data voltage Vdata from the data driver 400 via the data line DL, and receives a high potential driving voltage ELVDD and a low potential driving voltage ELVSS from the power supply 500.

The gate line GL supplies the scan signal SC and an emission control signal EM, and the data line DL supplies the data voltage Vdata. In addition, according to various embodiments, the gate line GL may include a plurality of scan lines SCL for supplying the scan signal SC and an emission control line EML for supplying the emission control signal EM. In addition, the plurality of pixels P may further include a power line VL to receive a reference voltage VREF and a reset voltage VAR.

In addition, each of the pixels P includes a light-emitting element and a pixel circuit. The pixel circuit includes a plurality of switching elements, a driving element, and a capacitor. In this regard, each of the switching element and the driving element may include a thin-film transistor. In the pixel circuit, the driving element controls an amount of current supplied to the light-emitting element based on the data voltage to adjust an amount of light emitted from the light-emitting element. In addition, the plurality of switching elements receive the scan signal SC supplied through the plurality of scan lines SCL and the emission control signal EM supplied through the emission control line EML to operate the pixel circuit.

The display panel 100 may be embodied as a non-transmissive display panel or a transmissive display panel. The transmissive display panel may be applied to a transparent display device in which an image is displayed on a screen and a real object in the background is visible to a viewer in front of the display device. The display panel 100 may be manufactured as a flexible display panel. The flexible display panel may be embodied as an OLED panel using a plastic substrate.

Touch sensors may be disposed on the display panel 100. The touch input may be sensed using separate touch sensors or may be sensed through the pixels P. The touch sensors may be disposed on the screen of the display panel in an on-cell type or an add-on type or be embodied as in-cell type touch sensors embedded in the display panel 100.

The controller 200 processes image data RGB input from a host system to be suitable for a size and resolution of the display panel 100 and supplies the processed image data RGB to the data driver 400. The controller 200 generates a gate control signal GCS and a data control signal DCS using synchronization signals input from an external source, for example, a clock signal CLK, a data enable signal DE, a horizontal synchronization signal Hsync, and a vertical synchronization signal Vsync. The controller 200 controls the gate driver 300 and the data driver 400 by supplying the gate control signal GCS and the data control signal DCS to the gate driver 300 and the data driver 400, respectively.

The controller 200 may be combined with various processors, for example, a microprocessor, a mobile processor, an application processor, and the like, depending on a type of a device on which the controller 200 is mounted.

The host system may be any one of a television (TV) system, a set-top box, a navigation system, a personal computer (PC), a home theater system, a mobile device, a wearable device, and a vehicle system.

The controller 200 generates a signal so that the pixel P may operate at various refresh rates. The refresh rate may be defined as the number of frames transmitted per second. That is, the controller 200 generates operation-related signals such that the pixel may operate in a Variable Refresh Rate (VRR) mode, or a refresh rate thereof may be switchable to between different refresh rates. For example, the controller 200 may simply change a rate of a clock signal or may generate a synchronization signal to generate a horizontal blank or a vertical blank.

The controller 200 generates the gate control signal GCS for controlling an operation timing of the gate driver 300 and the data control signal DSC for controlling an operation timing of the data driver 400 based on the timing signals Vsync, Hsync, and DE received from the host system. The controller 200 controls the operation timings to synchronize the gate driver 300 and the data driver 400 with each other.

The gate driver 300 supplies the scan signal SC to the gate line GL according to the gate control signal GCS supplied from the controller 200. The gate driver 300 may be disposed on one side or each of both opposing sides of the display panel 100 in a gate in panel (GIP) manner.

In the organic light-emitting display device, the gate driver 300 supplies the scan signal SC and the emission control signal EM to the display panel 100. The scan signal SC includes a scan pulse that swings to between the gate low voltage VGL and the gate high voltage VGH. The emission control signal EM includes an emission control signal pulse that swings to between the gate low voltage VEL and the gate high voltage VEH. The scan pulse is synchronized with the data voltage Vdata and is used to select pixels P of a line to which the data is to be written. The emission control signal pulse defines an emission time of the pixels P.

The gate driver 300 includes at least one emission control signal driver 310 and at least one scan driver 320. The emission control signal driver 310 outputs the emission control signal pulse in response to a start pulse and a shift clock from the controller 200, and sequentially shifts the emission control signal pulse according to the shift clock. The scan driver 320 outputs a scan pulse in response to a start pulse and a shift clock from the controller 200, and shifts the scan pulse according to a shift clock.

The data driver 400 converts the image data RGB into the data voltage Vdata according to the data control signal DCS supplied from the controller 200, and supplies the converted data voltage Vdata to the pixel P through the data line DL.

Although FIG. 1 illustrates that one data driver 400 is disposed on one side of the display panel 100, the number and arrangement position of the data driver 400 are not limited thereto. That is, the data driver 400 may be embodied as a plurality of integrated circuits (ICs) which may be disposed on one side of the display panel 100 and may be separately arranged.

The power supply 500 generates DC power required for driving the pixel array of the display panel 100, the gate driver 300, and the data driver 400 using a DC-DC converter. The DC-DC converter may include a charge pump, a regulator, a buck converter, a boost converter, etc. The power supply 500 may receive a DC input voltage applied from the host system and generate a DC voltage such as the gate low voltage VGL or VEL, the gate high voltage VGH or VEH, the high potential driving voltage ELVDD, the low potential driving voltage ELVSS, the reset voltage VAR, the reference voltage VREF, etc. The gate low voltages VGL and VEL and the gate high voltages VGH and VEH are supplied to the level shifter and the gate driver 300. The high potential driving voltage ELVDD, the low potential driving voltage ELVSS, the reset voltage VAR, and the reference voltage VREF are supplied to the pixels P.

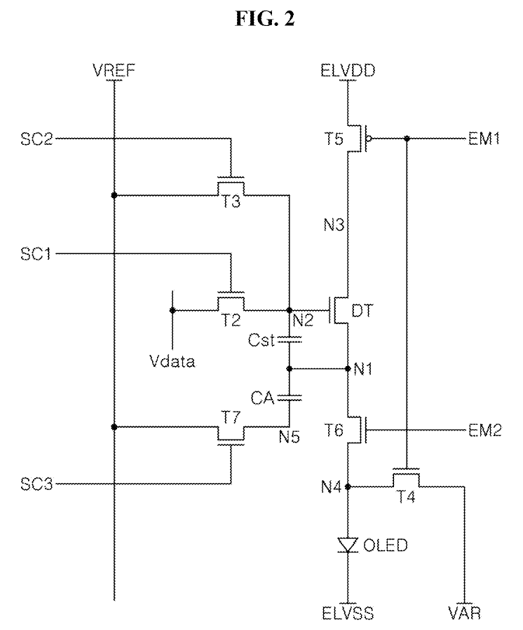

FIG. 2 is a circuit diagram of a pixel in an organic light-emitting display device according to an embodiment of the present disclosure.

Referring to FIG. 2, each of the plurality of pixels P may include a pixel circuit having a driving transistor DT and a light-emitting element OLED connected to the pixel circuit.

The pixel circuit may control a driving current flowing through the light-emitting element OLED to drive the light-emitting element OLED. The pixel circuit may include the driving transistor DT, second to seventh transistors T2 to T7, a storage capacitor Cst, and a compensation capacitor CA.

Each of the driving transistor DT and the second to seventh transistors T2 to T7 may include a first electrode, a second electrode, and a gate electrode. One of the first electrode and the second electrode may be a source electrode, and the other of the first electrode and the second electrode may be a drain electrode.

Each of the driving transistor DT and the second to seventh transistors T2 to T7 may be a P-type thin-film transistor or a N-type thin-film transistor. In the embodiment of FIG. 2, the driving transistor DT, the second, third, fourth, sixth, and seventh transistors T2, T3, T4, T6, and T7 may be N-type thin-film transistors, and the fifth transistor T5 may be an P-type thin-film transistor. In addition, the N-type thin-film transistor may be an oxide thin-film transistor, and the P-type thin-film transistor may be a polycrystalline silicon thin-film transistor.

As described above, each of the plurality of pixels includes the light-emitting element OLED, the driving transistor DT for driving the light-emitting element OLED, the storage capacitor Cst having one electrode connected to a gate electrode of the driving transistor DT and the other electrode connected to the source electrode of the driving transistor DT, and the compensation capacitor CA having one electrode connected to the other electrode of the storage capacitor Cst and the source electrode of the driving transistor DT.

In addition, each of the plurality of pixels includes the second transistor T2 having one electrode receiving the data voltage Vdata and the other electrode connected to the gate electrode of the driving transistor DT and one electrode of the storage capacitor Cst, the third transistor T3 having one electrode receiving the reference voltage VREF and the other electrode connected to the gate electrode of the driving transistor DT and one electrode of the storage capacitor Cst, and the fourth transistor T4 having one electrode connected to an anode electrode of the light-emitting element OLED and the other electrode receiving the reset voltage VAR.

In addition, each of the plurality of pixels includes the fifth transistor T5 having one electrode receiving the high potential driving voltage ELVDD and the other electrode connected to the drain electrode of the driving transistor DT, the sixth transistor T6 having one electrode connected to the source electrode of the driving transistor DT and the other electrode connected to the anode electrode of the light-emitting element OLED, and the seventh transistor T7 having one electrode receiving the reference voltage VREF and the other electrode connected to the other electrode of the compensation capacitor CA.

The driving transistor DT includes the source electrode connected to a first node N1, the gate electrode connected to a second node N2, and a drain electrode connected to a third node N3. The driving transistor DT provides a driving current to the light-emitting element OLED based on the data voltage Vdata applied to the gate electrode thereof.

The light-emitting element OLED includes the anode electrode and a cathode electrode. The anode electrode of the light-emitting element OLED is connected to a fourth node N4, and the cathode electrode of the light-emitting element OLED receives the low potential driving voltage ELVSS.

The storage capacitor Cst may be connected to and disposed between the second node N2 and the first node N1. The storage capacitor Cst may store therein or maintain the data voltage Vdata. In addition, the storage capacitor Cst may be used to sample a threshold voltage of the driving transistor DT.

The compensation capacitor CA may be connected to and disposed between the first node N1 and the fifth node N5. The compensation capacitor CA may maintain a potential of the first node N1 corresponding to the source electrode of the driving transistor DT. In addition, the compensation capacitor CA together with the storage capacitor Cst may be used to sample the threshold voltage of the driving transistor DT.

The second transistor T2 may include a first electrode connected to the data line DL (or receiving the data voltage Vdata), a second electrode connected to the second node N2, and a gate electrode receiving a first scan signal SC1. The second transistor T2 may be turned on in response to the first scan signal SC1, and may transmit the data voltage Vdata to the second node N2.

The third transistor T3 may include a first electrode receiving the reference voltage VREF, a second electrode connected to the second node N2, and a gate electrode receiving a second scan signal SC2. The third transistor T3 may be turned on in response to the second scan signal SC2 and may transmit the reference voltage VREF to the second node N2.

The fourth transistor T4 may include a first electrode receiving the reset voltage VAR, a second electrode connected to the fourth node N4, and a gate electrode receiving a first emission control signal EM1. The fourth transistor T4 may be turned on in response to the first emission control signal EM1 and may transmit the reset voltage VAR to the fourth node N4.

The fifth transistor T5 may include a first electrode receiving the high potential driving voltage ELVDD, a second electrode connected to the third node N3, and a gate electrode receiving the first emission control signal EM1. The fifth transistor T5 may be turned on in response to the first emission control signal EM1 and transmit the high potential driving voltage ELVDD to the third node N3.

The sixth transistor T6 may include a first electrode connected to the first node N1, a second electrode connected to the fourth node N4, and a gate electrode receiving a second emission control signal EM2. The sixth transistor T6 may be turned on in response to the second emission control signal EM2 and may transmit the driving current controlled by the driving transistor DT to the light-emitting element OLED via the fourth node N4. In addition, the sixth transistor T6 may be turned on in response to the second emission control signal EM2, and may transmit the reset voltage VAR transmitted thereto from the fourth transistor T4 to the first node N1.

The seventh transistor T7 may include a first electrode receiving the reference voltage VREF, a second electrode connected to the fifth node N5, and a gate electrode receiving a third scan signal SC3. The seventh transistor T7 may be turned on in response to the third scan signal SC3 and may transmit the reference voltage VREF to the fifth node N5.

A display device according to an embodiment of the present disclosure may be embodied as a variable refresh rate (VRR) mode display device. In the VRR mode, the display device operates at a constant frequency. When a high-speed operation is required, a refresh rate at which the data voltage Vdata is updated increases. Thus, the pixel operates at the increased refresh rate. When low power consumption or a low-speed operation is required, the refresh rate is lowered such that the pixel operates at the lowered refresh rate.

Each of the plurality of pixels P may operate only based on the refresh frame according to the refresh rate or may operate based on a combination of the refresh frame and an anode reset frame. In the present disclosure, the refresh frame may be defined as a period for which the data voltage Vdata is updated, and the anode reset frame may be defined as a period for which the data voltage Vdata is maintained without being updated. In the present disclosure, the combination of the refresh frame and the anode reset frame is repeated on an one set period basis.

For example, when the pixel operates at the refresh rate 120Hz, only the refresh frame may be repeated. That is, the refresh frame may be repeated 120 times within 1 second. One refresh frame period is 1/120=8.33ms, and one set period is also 8.33ms.

When the refresh rate is 60Hz, the refresh frame and the anode reset frame may be repeated alternately with each other. That is, the refresh frame and the anode reset frame may be alternately repeated with each other, such that each of the refresh frame and the anode reset frame may be repeated 60 times within 1 second. Thus, a period of each of one refresh frame and one anode reset frame is 0.5/60 = 8.33 ms, and one set period is 16.66 ms.

When the refresh rate is 1Hz, one frame may be composed of one refresh frame, and 119 anode reset frames subsequent to the one refresh frame. Furthermore, when the refresh rate is 1Hz, one frame may be composed of a plurality of refresh frames and a plurality of anode reset frames. In this regard, a period of each of one refresh frame and one anode reset frame is 1/120 = 8.33ms, and one set period is 1s.

In the refresh frame, a new data voltage Vdata is charged to apply the new data voltage Vdata to the driving transistor DT. In the anode reset frame, the data voltage Vdata of a previous frame is maintained and used. The anode reset frame may also be referred to as a hold frame in the sense that the data voltage Vdata of the previous frame is maintained and used.

First, the operation of the pixel circuit and the light-emitting element in the refresh frame will be described.

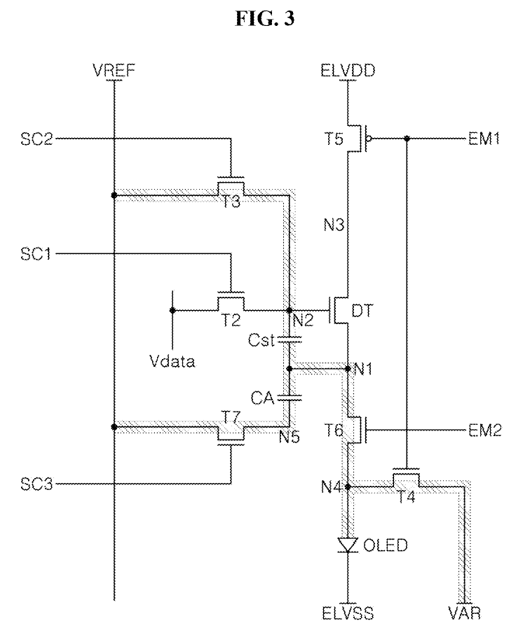

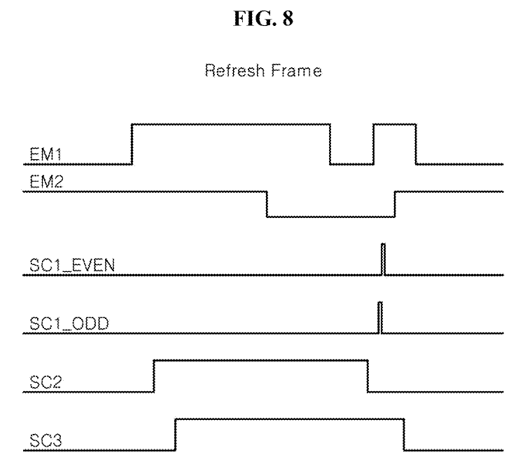

FIG. 3 is a circuit diagram of a pixel showing an initialization operation in an organic light-emitting display device according to an embodiment of the present disclosure. FIG. 8 is a timing diagram illustrating a refresh frame operation in an organic light-emitting display device according to an embodiment of the present disclosure. Referring to FIG. 8, the refresh frame may include an initialization period, a sampling period, a program period, and an emission period.

Referring to FIGS. 3 and 8, the pixel circuit operates for the refresh frame such that the initialization period is included in the refresh frame. The initialization period refers to a period for which the first node N1, the second node N2, the fourth node N4, and the fifth node N5 of the pixel circuit are initialized. During the initialization period, the gate electrode of the driving transistor DT connected to the second node N2 and the storage capacitor Cst may be initialized, the source electrode of the driving transistor DT connected to the first node N1 may be initialized, the anode electrode of the light-emitting element OLED connected to the fourth node N4 may be initialized, and the compensation capacitor CA connected to the fifth node N5 may be initialized.

In the initialization period, the second scan signal SC2, the third scan signal SC3, the first emission control signal EM1, and the second emission control signal EM2 are applied at a high voltage level, such that the third transistor T3, the fourth transistor T4, the sixth transistor T6, and the seventh transistor T7 are turned on. As the third transistor T3, the fourth transistor T4, the sixth transistor T6, and the seventh transistor T7 are turned on, the second node N2 and the fifth node N5 may be initialized with and to the reference voltage VREF, and the fourth node N4 and the first node N1 may be initialized with and to the reset voltage VAR.

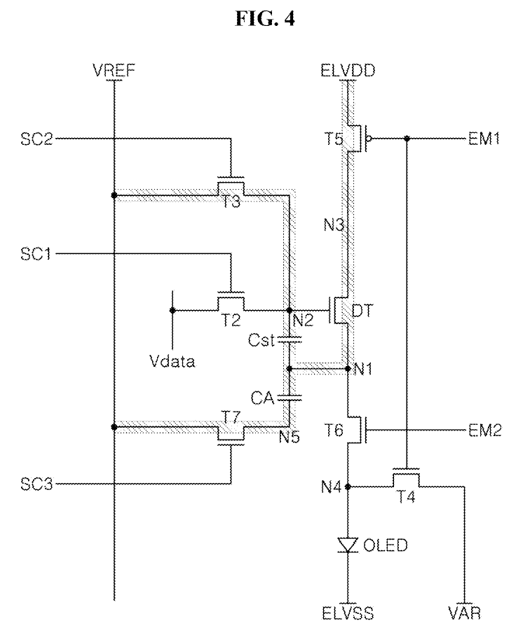

FIG. 4 is a circuit diagram of a pixel showing a sampling operation in an organic light-emitting display device according to an embodiment of the present disclosure.

Referring to FIGS. 4 and 8, the pixel circuit may operate for the refresh frame such that a sampling period is included in the refresh frame. The sampling period refers to a period for which a threshold voltage Vth of the driving transistor DT is sampled. During the sampling period, the threshold voltage Vth of the driving transistor DT may be sampled via the storage capacitor Cst and the compensation capacitor CA.

In the sampling period, the second scan signal SC2 and the third scan signal SC3 are applied at a high voltage level, the first emission control signal EM1 is applied at a low voltage level, such that the third transistor T3, the fifth transistor T5, the seventh transistor T7, and the driving transistor DT are turned on. As the third transistor T3, the fifth transistor T5, the seventh transistor T7, and the driving transistor DT are turned on, the high potential driving voltage ELVDD is transmitted to the third node N3, and the second node N2 and the fifth node N5 are maintained at the reference voltage VREF, so that the threshold voltage of the driving transistor DT may be transmitted to the first node N1 and sampled.

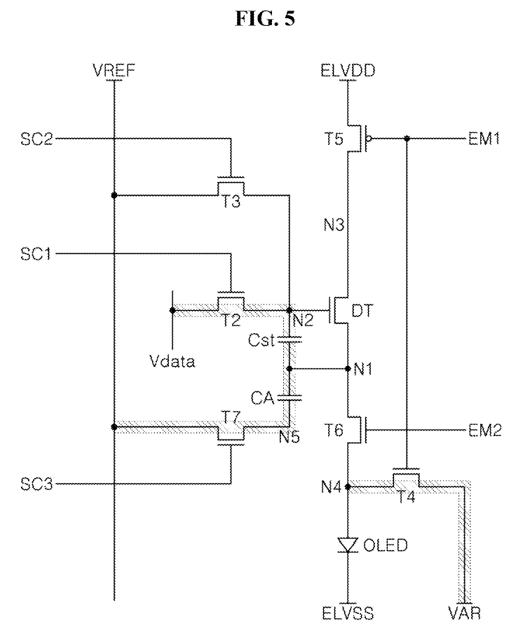

FIG. 5 is a circuit diagram of a pixel showing a program operation in an organic light-emitting display device according to an embodiment of the present disclosure.

Referring to FIGS. 5 and 8, the pixel circuit may operate for the refresh frame such that a program period is included in the refresh frame. The program period refers to a period for which the data voltage Vdata is stored in the storage capacitor Cst.

In the program period, the first scan signal SC1, the third scan signal SC3, and the first emission control signal EM1 are applied at a high voltage level, such that the second transistor T2, the fourth transistor T4, and the seventh transistor T7 are turned on. A first scan signal SC1 may include an odd-numbered first scan signal SC1_ODD provided to an odd-numbered gate line and an even-numbered first scan signal SC1_EVEN provided to an even-numbered gate line.

In the program period, as the second transistor T2, the fourth transistor T4, and the seventh transistor T7 are turned on, the data voltage Vdata is transferred to the second node N2, the reset voltage VAR is transferred to the fourth node N4, and the fifth node N5 is maintained at the reference voltage VREF, so that the data voltage Vdata is stored in the storage capacitor Cst.

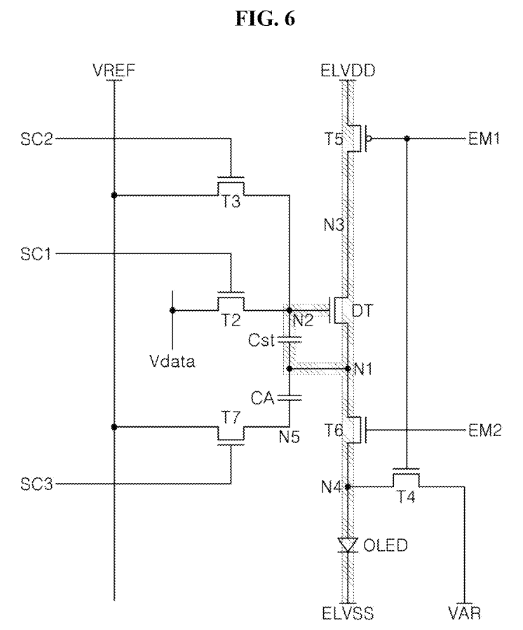

FIG. 6 is a circuit diagram of a pixel showing a light-emitting operation in an organic light-emitting display device according to an embodiment of the present disclosure.

Referring to FIG. 6 and FIG. 8, the pixel circuit may operate for the refresh frame such that a light emission period is included in the refresh frame. The light emission period refers to a period for which the threshold voltage Vth of the sampled driving transistor DT is compensated for, and the light-emitting element OLED emits light based on the driving current corresponding to the data voltage Vdata stored in the storage capacitor Cst.

In the emission period, the first emission control signal EM1 is applied at a low voltage level, the second emission control signal EM2 is applied at a high voltage level, such that the fifth transistor T5, the sixth transistor T6, and the driving transistor DT are turned on. As the fifth transistor T5, the sixth transistor T6, and the driving transistor DT are turned on, the high potential driving voltage ELVDD is transmitted to the third node N3, and the driving current corresponding to the data voltage Vdata is provided to the light-emitting element OLED.

Next, the operation of the pixel circuit and the light-emitting element in the anode reset frame will be described.

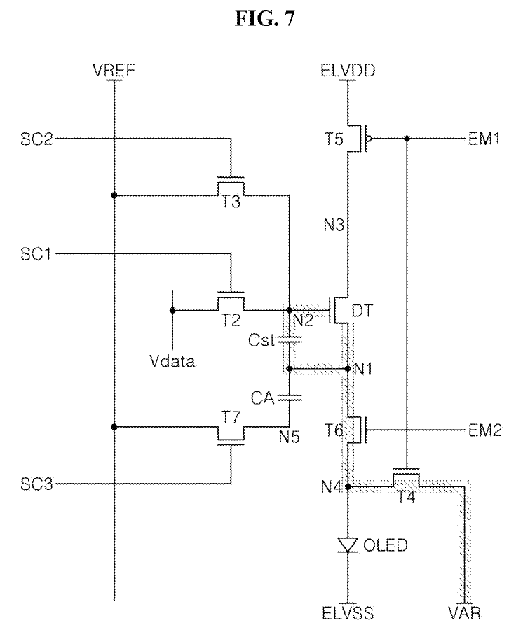

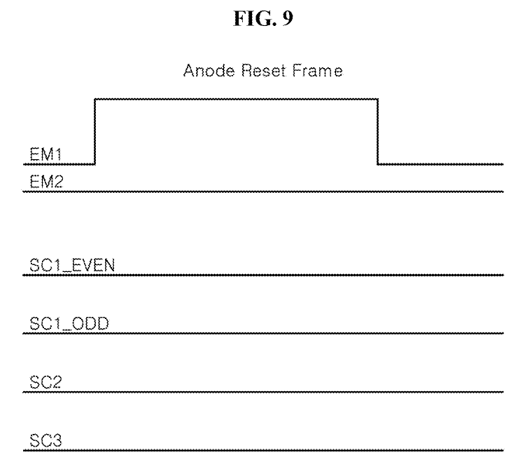

FIG. 7 is a circuit diagram of a pixel showing an anode reset operation in an organic light-emitting display device according to an embodiment of the present disclosure. FIG. 9 is a timing diagram illustrating an anode reset frame operation in an organic light-emitting display device according to an embodiment of the present disclosure.

Referring to FIGS. 7 and 9, the pixel circuit may operate for in the anode reset frame such that an anode reset period is included in the anode reset frame. The anode reset frame refers to a period for which the data voltage Vdata of the refresh frame is maintained and used. Therefore, unlike the refresh frame, the anode reset frame does not require the initialization period, the sampling period, and the program period.

In the anode reset period, the first light emission control signal EM1 and the second light emission control signal EM2 are applied at a high voltage level, such that the fourth transistor T4 and the sixth transistor T6 are turned on. As the fourth transistor T4 and the sixth transistor T6 are turned on, the first node N1 and the fourth node N4 may be reset to the reset voltage VAR, and the second node N2 may be maintained at the data voltage Vdata.

In addition, the pixel circuit may operate for the anode reset frame such that the emission period is included in the anode reset frame. Since the operation of the emission period of the anode reset frame is the same as the operation of the emission period of the refresh frame, a description thereof will be omitted.

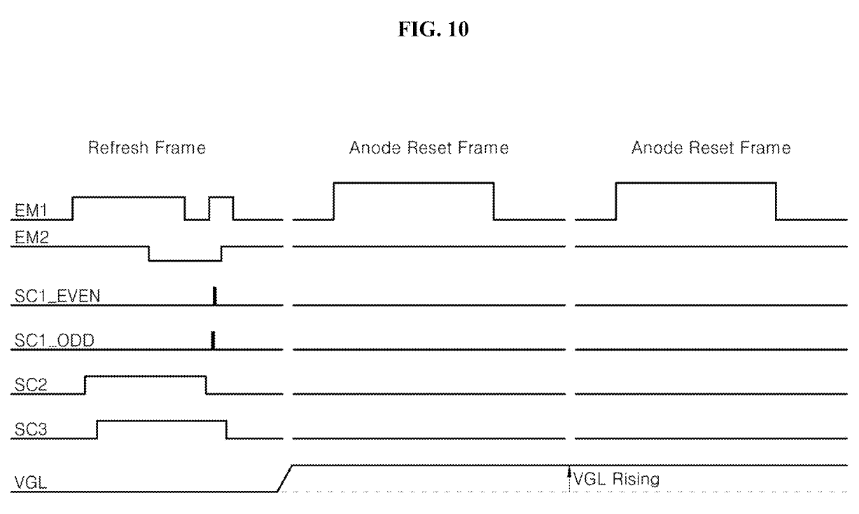

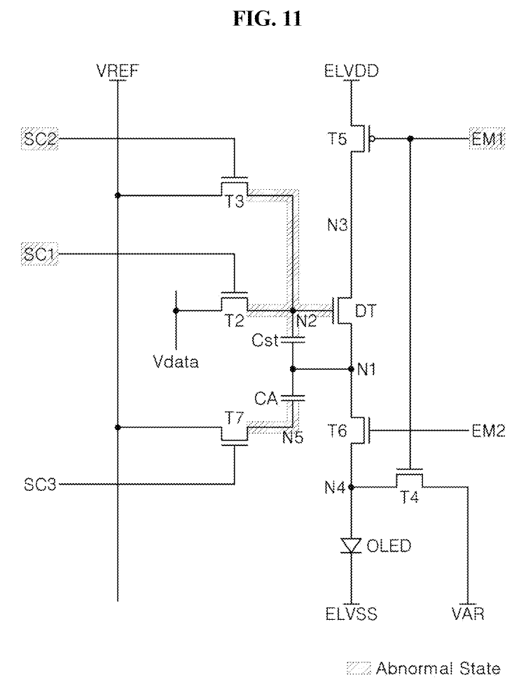

FIG. 10 is a timing diagram illustrating a low frequency operation in an organic light-emitting display device according to an embodiment of the present disclosure. FIG. 11 is a circuit diagram illustrating a pixel state in the low frequency operation of FIG. 10.

The present disclosure proposes a method for suppressing a front of screen (FOS) problem such as flashing (Flashing) that occurs when entering power-off under a low frequency operation condition via application of a high frequency operation before entering the power off. In the low frequency operation state, the FOS problem such as flashing may occur due to the occurrence of an abnormal state resulting from the rise of the gate low voltage VGL and the stress of the second node N2 and the fifth node N5 as shown in FIGS. 10 and 11. However, in the high frequency operation state, the FOS problem may be suppressed due to non-occurrence of power fluctuation and by resolving the abnormal state via refreshing of each node of the pixel.

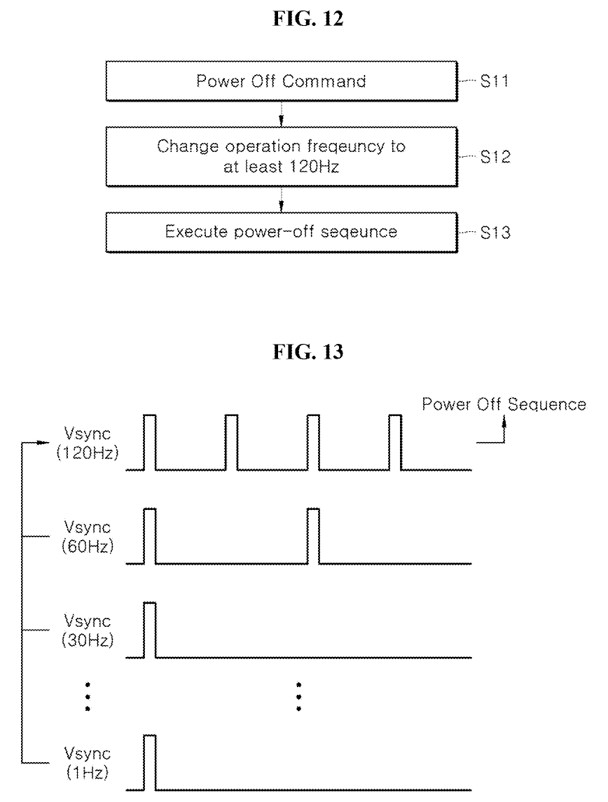

FIG. 12 is a flowchart illustrating a power-off operation in an organic light-emitting display device according to an embodiment of the present disclosure. FIG. 13 is a timing diagram illustrating a power-off operation in an organic light-emitting display device according to an embodiment of the present disclosure.

Referring to FIGS. 12 and 13, when a power-off command is input in S11, the display device changes an operation frequency to at least 120 Hz so that each node of the pixel is refreshed in the refresh frame in S12. After at least one refresh frame has elapsed, the display device enters and executes a power-off sequence in S13.

During the power-off, the FOS problem such as flashing may occur depending on the current operation frequence state. In which regard, the flashing is strongest in a 1Hz operation condition in which the number of anode reset frames is 119, and in the operation frequency state of 30Hz or higher in which the number of anode reset frames is 3, the flashing is not recognized by the user during the power-off.

The stress level of the pixel decreases as the number of anode reset frames decreases and the level of the FOS problem is weakened in proportion to the decrease in the stress level of the pixel. For this reason, although the current operation frequency state cannot be predicted, the present disclosure proposes a method for changing the operation frequency to at least 120Hz regardless of the current frequency operation state, and then entering and executing a power-off sequence. When the power is turned off, the refresh frame operation at 120 Hz or more may be identified based on the vertical synchronization signal Vsync.

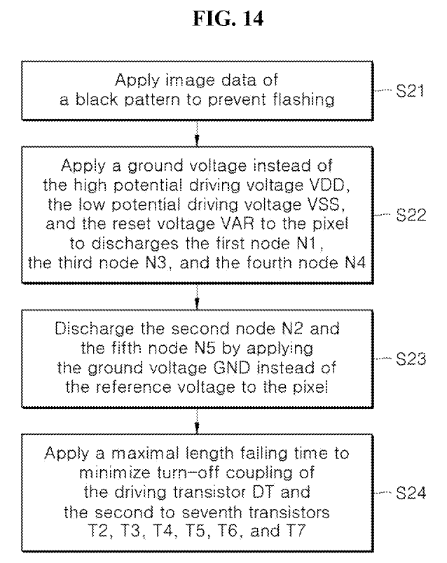

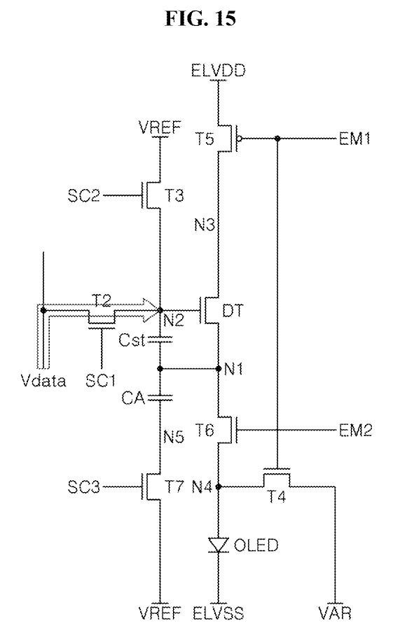

FIG. 14 is a flowchart illustrating a power-off sequence in an organic light-emitting display device according to an embodiment of the present disclosure. FIGS. 15 to 18 are circuit diagrams of a pixel showing a power-off sequence in an organic light-emitting display device according to an embodiment of the present disclosure.

Hereinafter, the power-off sequence will be described in detail. The power-off sequence may sequentially remove the remaining charges trapped in the node of the pixel including the oxide TFT. This may maintain the performance of the element and prevent the abnormal FOS phenomenon.

The power-off sequence is executed as follows. First, as shown in FIGS. 14 and 15, the display device applies image data of a black pattern to prevent flashing in S21. The display device may turn on the second transistor T2 to apply the data voltage Vdata of the black pattern to the second node N2.

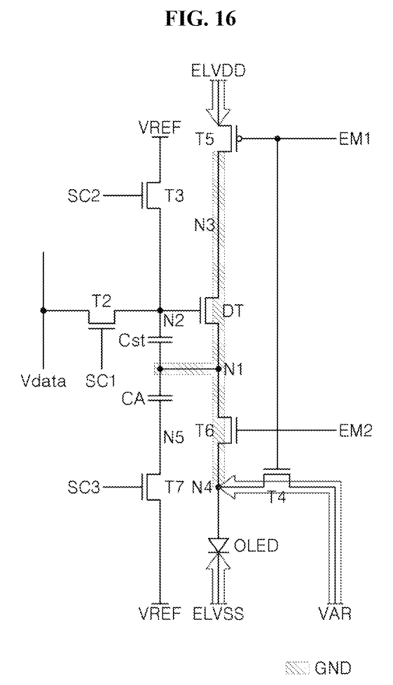

Next, as shown in FIGS. 14 and 16, the display device applies the ground voltage GND instead of the high potential driving voltage ELVDD, the low potential driving voltage ELVSS, and the reset voltage VAR to the pixel to discharges the first node N1, the third node N3, and the fourth node N4 in S22. The display device may turn on the fourth transistor T4, the fifth transistor T5 and the sixth transistor T6 to apply the ground voltage GND instead of the high potential driving voltage ELVDD, the low potential driving voltage ELVSS and the reset voltage VAR to the pixel.

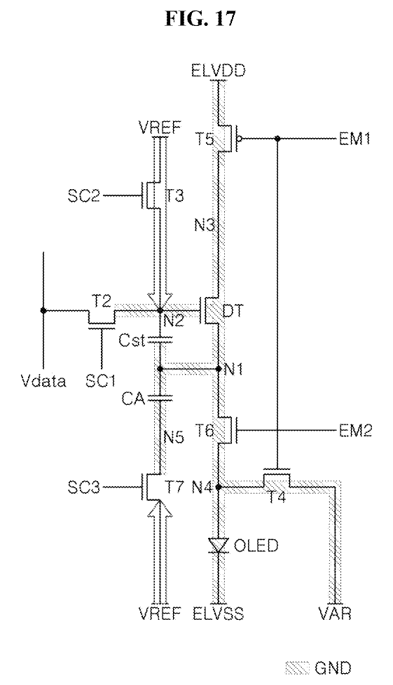

Next, as shown in FIGS. 14 and 17, the display device discharges the second node N2 and the fifth node N5 by applying the ground voltage GND instead of the reference voltage VREF to the pixel in S23. The display device may turn on the third transistor T3 and the seventh transistor T7 to apply the ground voltage GND instead of the reference voltage VREF to the pixel.

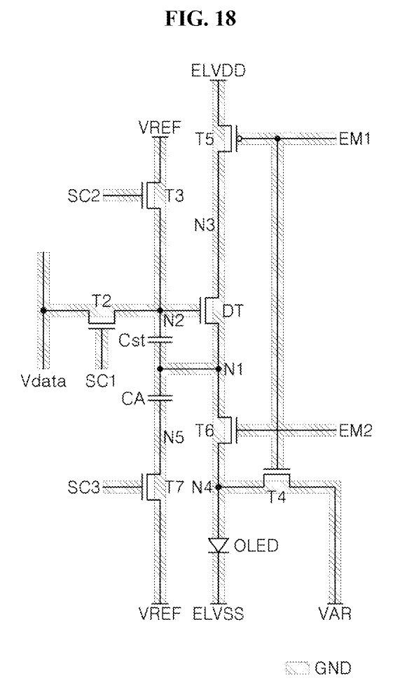

Next, as shown in FIGS. 14 and 18, the display device applies a maximal length falling time to minimize the turn-off coupling of the driving transistor DT and the second to seventh transistors T2, T3, T4, T5, T6, and T7 in S24. The display device may turn off the second to seventh transistors T2, T3, T4, T5, T6 and T7 to maintain a potential of each of a plurality of nodes of the pixel at the ground voltage GND for a predetermined time duration of greater.

The display device may discharge residual charges in each node of the pixel via the application of the power-off sequence as described above, thereby maintaining the performance of the element and preventing the FOS problem such as flashing.

As described above, the display device is configured for suppressing the FOS problem that may occur when entering the power-off in the low frequency operation condition in the pixel including a plurality of oxide TFTs. To this end, according to the present disclosure, when the power-off command is input, the operation frequency is changed to 120 Hz, and after the operation frequency has been changed thereto, the display device enters and executes the power-off sequence.

Accordingly, the display device may reduce the rising of the gate low voltage VGL and the stress of the second node N2 and the fifth node N5 of the pixel, and discharge the residual charges in the pixel via the power-off sequence, thereby maintaining the performance of the element and suppressing the FOS problem that may otherwise occur. In this manner, the FOS related performance of the display may be improved.

Display devices according to various aspects and various embodiments of the present disclosure may be described as follows.

A first aspect of the present disclosure provides a display device comprising: a light-emitting element; a driving transistor configured to drive the light-emitting element; a storage capacitor having a first electrode connected to a gate electrode of the driving transistor and a second electrode connected to a source electrode of the driving transistor; a compensation capacitor having a first electrode connected to a second electrode of the storage capacitor and a source electrode of the driving transistor; and at least one transistor configured to transmit at least one of a reference voltage, a reset voltage, and a high potential driving voltage to a pixel, wherein the display device is configured to: upon receiving a power-off command, change an operation frequency of the pixel to a changed operation frequency, and to perform a refresh frame operation of refreshing the pixel, based on the changed operation frequency; and after the refresh frame operation, execute a power-off sequence.

In accordance with some embodiments of the first aspect, the display device is configured to initialize the storage capacitor, the compensation capacitor, an anode electrode of the light-emitting element, and the gate electrode and the source electrode of the driving transistor in the refresh frame operation based on the changed operation frequency.

In accordance with some embodiments of the first aspect, in the power-off sequence, the display device is configured to: apply a data voltage corresponding to a black pattern to the pixel; apply a ground voltage instead of each of the high potential driving voltage, a low potential driving voltage, and the reset voltage to the pixel to discharge residual charges of a drain electrode and the source electrode of the driving transistor; apply the ground voltage instead of the reference voltage to the pixel to discharge residual charges of the storage capacitor and the compensation capacitor; and maintain a potential of each of a plurality of nodes of the pixel at the ground voltage for a predetermined time duration or greater to minimize turn-off coupling of the at least one transistor.

In accordance with some embodiments of the first aspect, the pixel includes: a first transistor having a first electrode receiving a data voltage and a second electrode connected to the gate electrode of the driving transistor and a first electrode of the storage capacitor; a second transistor having one electrode receiving the reference voltage and a second electrode connected to the gate electrode of the driving transistor and a first electrode of the storage capacitor; a third transistor having a first electrode connected to an anode electrode of the light-emitting element and a second electrode receiving the reset voltage; a fourth transistor having a first electrode receiving the high potential driving voltage and a second electrode connected to a drain electrode of the driving transistor; a fifth transistor having a first electrode connected to the source electrode of the driving transistor and a second electrode connected to the anode electrode of the light-emitting element; and a sixth transistor having a first electrode receiving the reference voltage and a second electrode connected to a second electrode of the compensation capacitor.

In accordance with some embodiments of the first aspect, each of the driving transistor, the first, second, third, fifth, and sixth transistors is embodied as an N-type thin-film transistor, and the fourth transistor is embodied as a P-type thin-film transistor.

In accordance with some embodiments of the first aspect, in the refresh frame operation based on the changed operation frequency, the display device is configured to: turn on the second transistor and the sixth transistor to initialize the storage capacitor, the compensation capacitor, and the gate electrode of the driving transistor using the reference voltage; and turn on the third transistor and the fifth transistor to initialize the anode electrode of the light-emitting element and the source electrode of the driving transistor using the reset voltage.

In accordance with some embodiments of the first aspect, in the power-off sequence, the display device is configured to: turn on the first transistor to apply a data voltage of a black pattern to the storage capacitor; turn on the third transistor, the fourth transistor and the fifth transistor and apply a ground voltage instead of each of the high potential driving voltage, a low potential driving voltage, and the reset voltage to the pixel, thereby discharging residual charges of the drain electrode and the source electrode of the driving transistor; turn on the second transistor and the sixth transistor and apply the ground voltage instead of the reference voltage to the pixel, thereby discharging residual charges of the storage capacitor and the compensation capacitor; and turn off the first to sixth transistors to maintain a potential of each of a plurality of nodes of the pixel at the ground voltage for a predetermined time duration of greater.

In accordance with some embodiments of the first aspect, upon receiving the power-off command, the display device is configured to change the operation frequency to a high frequency so that an anode reset frame is deactivated but only a refresh frame used in the refresh frame operation is activated.

In accordance with some embodiments of the first aspect, the high frequency is set to at least 120Hz.

In accordance with some embodiments of the first aspect, in response to a vertical synchronization signal, the display device is configured to perform the refresh frame operation at least one time and then execute the power-off sequence.

A second aspect of the present disclosure provides a display device comprising a display panel including a plurality of pixels, wherein each of the plurality of pixels includes: a light-emitting element; a driving transistor configured to drive the light-emitting element; a storage capacitor having a first electrode connected to a gate electrode of the driving transistor and a second electrode connected to a source electrode of the driving transistor; a compensation capacitor having a first electrode connected to a second electrode of the storage capacitor and the source electrode of the driving transistor; a first transistor having a first electrode receiving a data voltage and a second electrode connected to the gate electrode of the driving transistor and a first electrode of the storage capacitor; a second transistor having a first electrode receiving a reference voltage and a second electrode connected to the gate electrode of the driving transistor and a first electrode of the storage capacitor; a third transistor having a first electrode connected to an anode electrode of the light-emitting element and a second electrode receiving a reset voltage; a fourth transistor having a first electrode receiving a high potential driving voltage and a second electrode connected to a drain electrode of the driving transistor; a fifth transistor having a first electrode connected to the source electrode of the driving transistor and a second electrode connected to the anode electrode of the light-emitting element; and a sixth transistor having a first electrode receiving the reference voltage and a second electrode connected to a second electrode of the compensation capacitor, wherein the display device is configured to: upon receiving a power-off command, change an operation frequency of the pixel to a changed operation frequency, and to perform a refresh frame operation of refreshing the pixel, based on the changed operation frequency; and after the refresh frame operation, execute a power-off sequence.

In accordance with some embodiments of the second aspect, each of the driving transistor, the first, second, third, fifth, and sixth transistors is embodied as an N-type thin-film transistor, and the fourth transistor is embodied as a P-type thin-film transistor.

In accordance with some embodiments of the second aspect, the display device is configured to initialize the storage capacitor, the compensation capacitor, the anode electrode of the light-emitting element, and the gate electrode and the source electrode of the driving transistor in the refresh frame operation based on the changed operation frequency.

In accordance with some embodiments of the second aspect, in the power-off sequence, the display device is configured to: apply a data voltage corresponding to a black pattern to the pixel; apply a ground voltage instead of each of the high potential driving voltage, a low potential driving voltage, and the reset voltage to the pixel to discharge residual charges of a drain electrode and the source electrode of the driving transistor; apply the ground voltage instead of the reference voltage to the pixel to discharge residual charges of the storage capacitor and the compensation capacitor; and maintain a potential of each of a plurality of nodes of the pixel at the ground voltage for a predetermined time duration or greater to minimize turn-off coupling of the driving transistor and the first to sixth transistors.

In accordance with some embodiments of the second aspect, in the refresh frame operation based on the changed operation frequency, the display device is configured to: turn on the second transistor and the sixth transistor to initialize the storage capacitor, the compensation capacitor, and the gate electrode of the driving transistor using the reference voltage; and turn on the third transistor and the fifth transistor to initialize the anode electrode of the light-emitting element and the source electrode of the driving transistor using the reset voltage.

In accordance with some embodiments of the second aspect, in the power-off operation, the display device is configured to: turn on the first transistor to apply a data voltage of a black pattern to the storage capacitor; turn on the third transistor, the fourth transistor and the fifth transistor and apply a ground voltage instead of each of the high potential driving voltage, a low potential driving voltage, and the reset voltage to the pixel, thereby discharging residual charges of the drain electrode and the source electrode of the driving transistor; turn on the second transistor and the sixth transistor and apply the ground voltage instead of the reference voltage to the pixel, thereby discharging residual charges of the storage capacitor and the compensation capacitor; and turn off the first to sixth transistors to maintain a potential of each of a plurality of nodes of the pixel at the ground voltage for a predetermined time duration of greater.

In accordance with some embodiments of the second aspect, upon receiving the power-off command, the display device is configured to change the operation frequency to a high frequency so that an anode reset frame is deactivated but only a refresh frame used in the refresh frame operation is activated.

In accordance with some embodiments of the second aspect, in response to a vertical synchronization signal, the display device is configured to perform the refresh frame operation at least one time and then execute the power-off sequence.

In accordance with some embodiments of the second aspect, during an initialization period of the refresh frame, the display device is configured to transmit the reference voltage to a first node corresponding to the gate electrode of the driving transistor, and transmit the reset voltage to a second node corresponding to the anode electrode of the light-emitting element and a third node corresponding to the source electrode of the driving transistor.

In accordance with some embodiments of the second aspect, during a sampling period of the refresh frame, the display device is configured to sample a threshold voltage of the driving transistor using the storage capacitor and the compensation capacitor.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a light-emitting element;
a driving transistor configured to drive the light-emitting element;
a storage capacitor having a first electrode connected to a gate electrode of the driving transistor and a second electrode connected to a source electrode of the driving transistor;
a compensation capacitor having the first electrode connected to the second electrode of the storage capacitor and a source electrode of the driving transistor; and
at least one transistor configured to transmit at least one of a reference voltage, a reset voltage, and a high potential driving voltage to a pixel,
wherein the display device is configured to:
upon receiving a power-off command, change an operation frequency of the pixel to a changed operation frequency, and to perform a refresh frame operation of refreshing the pixel, based on the changed operation frequency; and
after the refresh frame operation, execute a power-off sequence.

2. The display device of claim 1, wherein the display device is configured to initialize the storage capacitor, the compensation capacitor, an anode electrode of the light-emitting element, and the gate electrode and the source electrode of the driving transistor in the refresh frame operation based on the changed operation frequency.

3. The display device of claim 1, wherein in the power-off sequence, the display device is configured to:
apply a data voltage corresponding to a black pattern to the pixel;
apply a ground voltage instead of each of the high potential driving voltage, a low potential driving voltage, and the reset voltage to the pixel to discharge residual charges of a drain electrode and the source electrode of the driving transistor;
apply the ground voltage instead of the reference voltage to the pixel to discharge residual charges of the storage capacitor and the compensation capacitor; and
maintain a potential of each of a plurality of nodes of the pixel at the ground voltage for a predetermined time duration or greater to minimize turn-off coupling of the at least one transistor.

4. The display device of claim 1, wherein the pixel includes:
a first transistor having a first electrode receiving a data voltage and a second electrode connected to the gate electrode of the driving transistor and the first electrode of the storage capacitor;
a second transistor having a first electrode receiving the reference voltage and a second other electrode connected to the gate electrode of the driving transistor and the first electrode of the storage capacitor;
a third transistor having a first electrode connected to an anode electrode of the light-emitting element and a second electrode receiving the reset voltage;
a fourth transistor having a first electrode receiving the high potential driving voltage and a second electrode connected to a drain electrode of the driving transistor;
a fifth transistor having a first electrode connected to the source electrode of the driving transistor and a second electrode connected to the anode electrode of the light-emitting element; and
a sixth transistor having a first electrode receiving the reference voltage and a second electrode connected to a second electrode of the compensation capacitor.

5. The display device of claim 4, wherein each of the driving transistor, the first, second, third, fifth, and sixth transistors is embodied as an N-type thin-film transistor, and the fourth transistor is embodied as a P-type thin-film transistor.

6. The display device of claim 4, wherein in the refresh frame operation based on the changed operation frequency, the display device is configured to:
turn on the second transistor and the sixth transistor to initialize the storage capacitor, the compensation capacitor, and the gate electrode of the driving transistor using the reference voltage; and
turn on the third transistor and the fifth transistor to initialize the anode electrode of the light-emitting element and the source electrode of the driving transistor using the reset voltage.

7. The display device of claim 4, wherein in the power-off sequence, the display device is configured to:
turn on the first transistor to apply a data voltage of a black pattern to the storage capacitor;
turn on the third transistor, the fourth transistor and the fifth transistor and apply a ground voltage instead of each of the high potential driving voltage, a low potential driving voltage, and the reset voltage to the pixel, thereby discharging residual charges of the drain electrode and the source electrode of the driving transistor;
turn on the second transistor and the sixth transistor and apply the ground voltage instead of the reference voltage to the pixel, thereby discharging residual charges of the storage capacitor and the compensation capacitor; and
turn off the first to sixth transistors to maintain a potential of each of a plurality of nodes of the pixel at the ground voltage for a predetermined time duration of greater.

8. The display device of claim 1, wherein upon receiving the power-off command, the display device is configured to change the operation frequency to a high frequency so that an anode reset frame is deactivated but only a refresh frame used in the refresh frame operation is activated.

9. The display device of claim 8, wherein the high frequency is set to at least 120Hz.

10. The display device of claim 8, wherein in response to a vertical synchronization signal, the display device is configured to perform the refresh frame operation at least one time and then execute the power-off sequence.

11. A display device comprising a display panel including a plurality of pixels,
wherein each of the plurality of pixels includes:
a light-emitting element;
a driving transistor configured to drive the light-emitting element;
a storage capacitor having a first electrode connected to a gate electrode of the driving transistor and a second electrode connected to a source electrode of the driving transistor;
a compensation capacitor having a first electrode connected to a second electrode of the storage capacitor and the source electrode of the driving transistor;
a first transistor having a first electrode receiving a data voltage and a second electrode connected to the gate electrode of the driving transistor and the first electrode of the storage capacitor;
a second transistor having a first electrode receiving a reference voltage a second other electrode connected to the gate electrode of the driving transistor and the first electrode of the storage capacitor;
a third transistor having a first electrode connected to an anode electrode of the light-emitting element and a second electrode receiving a reset voltage;
a fourth transistor having a first electrode receiving a high potential driving voltage and a second electrode connected to a drain electrode of the driving transistor;
a fifth transistor having a first electrode connected to the source electrode of the driving transistor and a second electrode connected to the anode electrode of the light-emitting element; and
a sixth transistor having a first electrode receiving the reference voltage and a second electrode connected to the second electrode of the compensation capacitor,
wherein the display device is configured to:
upon receiving a power-off command, change an operation frequency of the pixel to a changed operation frequency, and to perform a refresh frame operation of refreshing a pixel, based on the changed operation frequency; and
after the refresh frame operation, execute a power-off sequence.

12. The display device of claim 11, wherein each of the driving transistor, the first, second, third, fifth, and sixth transistors is embodied as an N-type thin-film transistor, and the fourth transistor is embodied as a P-type thin-film transistor.

13. The display device of claim 11, wherein the display device is configured to initialize the storage capacitor, the compensation capacitor, the anode electrode of the light-emitting element, and the gate electrode and the source electrode of the driving transistor in the refresh frame operation based on the changed operation frequency.

14. The display device of claim 11, wherein in the power-off sequence, the display device is configured to:
apply a data voltage corresponding to a black pattern to the pixel;
apply a ground voltage instead of each of the high potential driving voltage, a low potential driving voltage, and the reset voltage to the pixel to discharge residual charges of a drain electrode and the source electrode of the driving transistor;
apply the ground voltage instead of the reference voltage to the pixel to discharge residual charges of the storage capacitor and the compensation capacitor; and
maintain a potential of each of a plurality of nodes of the pixel at the ground voltage for a predetermined time duration or greater to minimize turn-off coupling of the driving transistor and the first to sixth transistors.

15. The display device of claim 11, wherein in the refresh frame operation based on the changed operation frequency, the display device is configured to:
turn on the second transistor and the sixth transistor to initialize the storage capacitor, the compensation capacitor, and the gate electrode of the driving transistor using the reference voltage; and
turn on the third transistor and the fifth transistor to initialize the anode electrode of the light-emitting element and the source electrode of the driving transistor using the reset voltage.

16. The display device of claim 11, wherein in the power-off sequence, the display device is configured to:
turn on the first transistor to apply a data voltage of a black pattern to the storage capacitor;
turn on the third transistor , the fourth transistor and the fifth transistor and apply a ground voltage instead of each of the high potential driving voltage, a low potential driving voltage, and the reset voltage to the pixel, thereby discharging residual charges of the drain electrode and the source electrode of the driving transistor;
turn on the second transistor and the sixth transistor and apply the ground voltage instead of the reference voltage to the pixel, thereby discharging residual charges of the storage capacitor and the compensation capacitor; and
turn off the first to sixth transistors to maintain a potential of each of a plurality of nodes of the pixel at the ground voltage for a predetermined time duration of greater.

17. The display device of claim 11, wherein upon receiving the power-off command, the display device is configured to change the operation frequency to a high frequency so that an anode reset frame is deactivated but only a refresh frame used in the refresh frame operation is activated.

18. The display device of claim 17, wherein in response to a vertical synchronization signal, the display device is configured to perform the refresh frame operation at least one time and then execute the power-off sequence.

19. The display device of claim 18, wherein during an initialization period of the refresh frame, the display device is configured to transmit the reference voltage to a first node corresponding to the gate electrode of the driving transistor, and transmit the reset voltage to a second node corresponding to the anode electrode of the light-emitting element and a third node corresponding to the source electrode of the driving transistor.

20. The display device of claim 19, wherein during a sampling period of the refresh frame, the display device is configured to sample a threshold voltage of the driving transistor using the storage capacitor and the compensation capacitor.
